(19) United States
(12) Patent Application Publication
(10) Pub. No.: US 2024/0085783 A1
(43) Pub. Date: Mar. 14, 2024

(54) OPTICAL DEVICE, METHOD FOR ADJUSTING A SETPOINT DEFORMATION AND LITHOGRAPHY SYSTEM

(71) Applicant: Carl Zeiss SMT GmbH, Oberkochen (DE)

(72) Inventors: Markus Raab, Schillingsfuerst (DE); Stefan Troeger, Stuetzengruen (DE); Sascha Bleidistel, Aalen (DE); Thilo Pollak, Neresheim (DE); Alexander Vogler, Aalen (DE); Klaus Gwosch, Aalen (DE); Andreas Koeniger, Aalen (DE); Matthias Manger, Aalen (DE)

(21) Appl. No.: 18/512,872

(22) Filed: Nov. 17, 2023

Related U.S. Application Data
(63) Continuation of application No. PCT/EP2022/063791, filed on May 20, 2022.

(30) Foreign Application Priority Data
May 27, 2021 (DE) 10 2021 205 425.0

(51) Int. Cl. G03F 7/00; G01L 1/22; G01L 1/24; G02B 6/02; G02B 6/293; G02B 6/38; G02B 6/42

(52) U.S. Cl. CPC G03F 7/0005; G01L 1/2287; G01L 1/246; G02B 6/02152; G02B 6/2935; G02B 6/3861; G02B 6/4298

(57) ABSTRACT

An optical apparatus for a lithography system comprises at least one optical element comprising an optical surface. The optical apparatus also comprises one or more actuators for deforming the optical surface. A strain gauge device is provided for determining the deformation of the optical surface. The strain gauge device comprises at least one optical fiber that maintains polarization.

### CROSS-REFERENCE TO RELATED APPLICATIONS

The present application is a continuation of, and claims benefit under 35 USC 120 to, international application PCT/EP2022/063791, filed May 20, 2022, which claims benefit under 35 USC 119 of German Application No 10 2021 205 425.0, filed May 27, 2021. The entire disclosure of each these applications is incorporated by reference herein.

### FIELD

The disclosure relates to an optical apparatus for a lithography system, having at least one optical element comprising an optical surface and having one or more actuators for deforming the optical surface.

The disclosure further relates to a method for setting a target deformation of an optical surface of an optical element for a lithography system via one or more actuators. Moreover, the disclosure relates to a lithography system, such as a projection exposure apparatus for semiconductor lithography, having an illumination system with a radiation source and an optical unit which comprises at least one optical element.

### BACKGROUND

Optical elements for guiding and shaping radiation in projection exposure apparatuses are known. In the known optical elements, a surface of the optical element frequently guides and shapes the light waves incident on the optical element. Therefore, to form an exact wavefront with desired properties, precise control of the shape of the surface is particularly advantageous.

Lithography systems are known which use ultraviolet radiation, in particular DUV (deep ultraviolet) and/or EUV (extreme ultraviolet) light in order to produce microlithographic structures with utmost precision. Here, the light of a radiation source is steered to a wafer to be exposed by way of a plurality of mirrors. An arrangement, a position, and a shape of the mirror make a decisive contribution here to the quality of the exposure.

For example, to increase the number of transistors on a chip further, it is desirable to develop existing lithography systems. It is known to attach of actuators to mirrors, wherein the actuators shape the mirrors in as many degrees of freedom as possible.

Further, various systems for actuating deformable mirrors are known.

It is known to integrate optical elements into optical apparatuses, which have actuators for force production in order to shape, in a targeted manner, the optical surface that interacts with the light waves.

It is known that the effect of the actuators on the optical surface is predicted, for example on the basis of modeling. However, influences neglected in the modeling may weaken a predictive power of the model.

Systems for deforming optical elements, as known, use closed-loop control to deform the optical surface and to set a target deformation. To this end, the deformation is measured via a sensor and, encoded in the form of an electrical signal, output to the actuators within the scope of closed-loop control. In general, known lithography systems do not allow a co-integration of a sensor with a sufficiently high measurement performance into the lithography system or optical element. For this reason, such optical apparatuses are operated within an open control chain or in a feedforward mode.

In certain known optical apparatuses, maintaining the target deformation as exactly as possible is decisive in relation to meeting the ever-increasing demands for increased precision, while the measures for exactly setting the target deformation, known to this end, are insufficient.

### SUMMARY

The present disclosure seeks to develop an improved optical apparatus, for example which enables precise shaping or precise setting of a target deformation of an optical surface.

The present disclosure also seeks to develop an improved method for setting a target deformation of an optical surface, for example which enables precise and reliable shaping or precise setting of a target deformation of the optical surface.

The present disclosure also seeks to develop a lithography system which avoids the disadvantages of the prior art, for example which enables forming precisely shaped wavefronts of radiation.

An optical apparatus according to the disclosure for a lithography system, such as projection exposure apparatus, comprises at least one optical element having an optical surface and one or more actuators for deforming the optical surface. According to the disclosure, a strain gauge device is provided for determining the deformation of the optical surface, the strain gauge device comprising at least one optical fiber and the optical fiber maintaining polarization.

Within the scope of the disclosure, a strain may also be understood to mean a contraction and/or compression.

Further, the mechanical deformation of the optical surface can serve to shape the optical surface and/or set a target deformation.

An optical apparatus according to the disclosure can allow independent control of an actual deformation of the optical surface by the envisaged strain gauge device. An optical apparatus according to the disclosure can thus enable a more precise and more reliable deformation of the optical surface than certain known systems, which do not allow control of the actual deformation of the optical surface. This can be desirable when the actuators are used for the deformation or for bringing about the deformation since the effect thereof on the precise shaping of the optical surface is frequently based on pure modeling. Using an optical apparatus according to the disclosure, the modeling can be complemented with and/or replaced by empirical measurements of the actual deformation.

Provision can be made for the at least one actuator to be in the form of an electrostrictive actuator. In this case, an embodiment as an electrostrictive actuator can be desirable in that electrostrictive actuators have a very small tendency to drift and a small tendency to exhibit hysteresis.

Provision can be made for the optical apparatus to comprise a plurality of actuators for a deformation of the optical surface, with each individual actuator of the plurality of actuators being drivable.

By driving each individual actuator, it is possible to set profiles of the optical surface and/or optical element, especially of a mirror, in targeted fashion and hence correct the optical apparatus or lithography system, in which the optical apparatus is integrated, to the best possible extent.

A strain of the actuators can be described by formula (1) to a first approximation. Here, M describes an electrostrictive coefficient, which leads to a strain S as a result of the application of an electric field E. As is evident from formula (1), the electrostrictive coefficient M depends on the temperature ϑ of the actuator. Moreover, the strain S of the actuator depends on its stiffness s and an applied mechanical tension T. Further, a thermal component of the strain arises from multiplying the thermal coefficient of expansion CTE by the difference between the temperature ϑ and an initial temperature ϑ₀.

S(E,ϑ)=M(ϑ)·E²+s·T+CTE·(θ−ϑ₀) (1)

For highly precise and constant closed-loop control of a position of the at least one actuator, it can be desirable for both a loss of strain of the at least one actuator on the basis of the electrostrictive effect and the thermal strain to be corrected. To this end, provision can be made for the at least one actuator to use more than 80% of its working distance for the self-correction of thermal expansions or thermal effects.

Accordingly, it can be desirable for a highly precise positioning or deformation of the optical surface to be rendered possible by virtue of a temperature calibration being accompanied by modeling and calibration of an electrostrictive and thermal hysteresis and of a drift of the actuator.

To enable a reflection of EUV light, highly complex coatings are frequently used to form the optical surface. Such coatings can profit to a particularly great extent from a control of the effect of the at least one actuator since an overload of or excess strain on the optical surface may lead to the complex coating arranged thereon being damaged or destroyed.

Provision can be made for the optical element to comprise an optical surface formed continuously and/or in one piece and for the optical element to not be a field facet mirror in particular. As a result, the optical surface can at least approximately form a free-form surface.

Provision can be made for the optical apparatus to be optimized for use in other fields of application, rather than for use in the lithography system. By way of example, the optical apparatus can be provided for use as a part of a space mirror.

Provision can be made for a plurality of strain gauge devices to be present as part of the optical apparatus. If a plurality of strain gauge devices are present, provision can be made for the plurality of strain gauge devices to share other constituent parts of the optical apparatus.

The use of an optical fiber as a part of the strain gauge device can be desirable in that optical fibers can be used to guide light to different positions of the optical apparatus for measurement purposes. From these positions, the light can be reflected and/or transmitted by the optical fiber, for example for the purpose of measuring properties of the light. In this context, optical fibers are very reliable and precise light guides, which are also available with very small diameters. The use of optical fibers can be desirable when optical apparatuses which comprise very delicate components are used, with the optical fibers possibly likewise having a very delicate embodiment.

Strain gauge arrangements based on impedance measurements, which are known, frequently involve a large number of electrical conductors which may restrict a function of an optical component.

Using a polarization-maintaining optical fiber, it is possible to separate or decouple those influences on the deformation of the optical surface which can be traced back to a change in temperature from those influences on the deformation of the optical surface which can be traced back to a strain and/or distortion of the optical apparatus. This renders possible an even more accurate and precise control of the deformation or the precise shaping of the optical surface since the various influencing factors on the shape of the optical surface can be addressed and/or removed separately from one another.

A separation of temperature-induced influences can be desirable because temperature variations on the optical surface, such as during use in EUV lithography systems, may represent one of the largest disturbances in relation to the deformation of the optical element. For example, the temperature of the optical surface or the optical element may vary between 20° C. and 40° C. during operation.

In a development of the optical apparatus according to the disclosure, provision can be made for the at least one optical fiber to comprise one or more fiber Bragg gratings with respective fiber interference spectra.

If the optical fiber comprises a fiber Bragg grating, then this can yield a fiber interference spectrum that is characteristic for the fiber Bragg grating. In this context, the fiber interference spectrum should be understood to be a wavelength-dependent change in radiation propagating through the fiber.

For example, the fiber Bragg grating has a characteristic filter bandwidth. Radiation at a wavelength within a spectral range determined by the filter bandwidth can be reflected by the fiber Bragg grating in the optical fiber. Radiation reflected thus can propagate backward in the optical fiber, counter to the original direction, and can be measured, for example.

Alternatively, the fiber interference spectrum may also be determined in a transmission configuration, whereby this yields a transmitted radiation spectrum in which the reflected range and the filter bandwidth are identifiable as a notch.

In this case, the fiber interference spectrum and the filter bandwidth, for example, are dependent on geometric properties of the fiber Bragg grating. In this context, a grating period of the fiber Bragg grating can be a decisive geometric property of the fiber Bragg grating.

The use of a fiber Bragg grating can desirable for use in a strain gauge device since strain on the optical fiber, and hence on the fiber Bragg grating, may also modify the geometric properties thereof. The change in the geometric properties, for example a compression or stretching of the grating period, also can yield a change in the fiber interference spectrum and hence, in particular, a change in a central wavelength of the filter bandwidth.

In this case, the central wavelength of the filter bandwidth is directly proportional to the grating period multiplied by twice an effective refractive index within the fiber Bragg grating.

A spectral width of the filter bandwidth depends on a length of the fiber Bragg grating and a degree of a refractive index change between adjacent refractive index regions. These parameters can also be modified, for example by stretching or compressing the fiber Bragg grating, and therefore are suitable for determining mechanical strains of the optical fiber and/or fiber Bragg grating.

As an alternative or in addition to an optical fiber and a fiber Bragg grating, other optical sensors may also be provided as part of the strain gauge device.

For example, other optical waveguides and other optical interference filters, especially Bragg gratings, may be provided. By way of example, an alternative or additional optical interference filter can be a line grating and/or a resonator and/or a simple slit stop. By way of example, the alternative and/or additional waveguide can be a rigidly formed light channel which is not in the form of an optical fiber. The optical waveguide or light channel can be designed to maintain polarization. Further, a puristic waveguide in the form of a free beam may also be provided.

The use of an optical single mode fiber as an optical fiber can be desirable because this can yield a particularly clear structure of the fiber interference spectrum.

For example, provision can be made for the fiber Bragg grating to be designed as a periodic microstructure which selectively reflects wavelengths.

Provision can be made for the fiber Bragg grating to be designed, such as to have a grating period, such that a frequency shift in the case of a strain caused by an intended use of the at least one actuator is 1 pm to 1 nm, such as 5 pm to 500 pm, for example 20 pm to 100 pm.

Provision can be made for the strain gauge device and/or the fiber Bragg grating to be designed in such a way that a strain resolution is 1 am to 1 nm, such as 5 am to 1 pm, for example 0.5 fm to 50 fm.

In a development of the optical apparatus according to the disclosure, provision can be made for the optical element to comprise a substrate element, on which the optical surface is arranged.

To obtain particularly good shaping and guidance of wavefronts, it can be desirable for the optical surface to be arranged or formed on a substrate element, with the at least one actuator deforming the substrate element by applying its force and thereby also bringing about a deformation of the optical surface. Such indirect action on the optical surface can be desirable because, in the case of complexly structured optical surfaces, these are protected from a direct application of force of the actuator as the latter is imparted through the substrate element.

Further, provision can be made for the strain gauge device to comprise an optical capturing device, for example a camera, which captures a strain of the substrate element and/or optical surface on the basis of a change, for example of an external contour and/or of optical properties, especially on a back side of the substrate element. The strain gauge device and the substrate element are mechanically decoupled in such an embodiment, but a transfer of information about the strain state of the substrate element is obtained in a different way.

Further, provision can be made for the fiber Bragg grating also to be formed in such a way that changes in the strain and/or temperature changes lead to changes in the reflected and/or transmitted fiber interference spectrum.

Provision can be made for the fiber Bragg grating also to be configured to measure the changes in temperature and/or a temperature of at least one measurement region.

As a result, the strain gauge device and/or the fiber Bragg grating can be used to measure the temperature.

In a development of the optical apparatus according to the disclosure, provision can be made for the at least one actuator to be connected to the substrate element by way of a connection layer, the latter optionally comprising an adhesive.

For example, provision can be made for the optical surface to be formed on the substrate element, for example by way of a coating and/or structuring.

To ensure a transfer of force between the at least one actuator and the substrate element, these may be connected to one another by way of a connection layer. This can be desirable because the at least one actuator and the substrate element can be produced separately from one another and can be put together only during an assembly of the optical apparatus. The connection layer which connects the at least one actuator to the substrate element is optionally formed from an adhesive or comprises an adhesive. In this case, the use of an adhesive enables great flexibility when assembling the optical apparatus.

Optionally, the at least one actuator may be arranged on a back side facing away from the optical surface.

In a development of the optical apparatus according to the disclosure, provision can be made for the strain gauge device to be at least partly arranged in the substrate element, optionally in a groove of the substrate element.

In this case, an embodiment of the optical apparatus in which the strain gauge device is arranged completely in the substrate element, optionally completely in the groove of the substrate element, is particularly advantageous.

If the strain gauge device comprises the fiber Bragg grating, it can be desirable for the fiber Bragg grating to be arranged in the substrate element.

An arrangement of the strain gauge device in a groove of the substrate element can be desirable in that a suitable installation space for the strain gauge device is created by the creation of the groove, for example by way of a cutting and/or milling method. This can especially apply if the strain gauge device comprises the optical fiber and/or the fiber Bragg grating.

In terms of the installation shape, optical fibers are particularly suitable for being fit into a groove.

Further, an arrangement of the strain gauge device, and in this case of an optical fiber and/or a fiber Bragg grating in particular, in the groove enables particularly strong mechanical coupling to strains and/or distortions of the body in which the groove is formed. Thus, if the substrate element experiences a distortion and/or strain in the above-described case, then this strain can be transferred to the strain gauge device particularly well should the strain gauge device be immersed in the substrate element or be arranged in a groove. As a result, a strain of the substrate element can be precisely mapped by the strain gauge device in a particularly advantageous manner from a metrological point of view.

An arrangement of the strain gauge device on the substrate element is further advantageous in that strains of the substrate element can be measured by the strain gauge device. Strains of the substrate element in turn allow a particularly meaningful prediction about deformations of the optical surface since the optical surface is arranged on the substrate element and more particularly is directly mechanically coupled therewith.

By way of example, provision can be made for the optical surface to be formed by a coating and/or structuring which is arranged on the substrate element. In this context, this may relate to applied coatings which are formed from a material that differs from that of the substrate element and/or to structurings or coatings which are formed by the material of the substrate element itself.

In such cases, there is a direct whole-area physical connection of the optical surface to the substrate element. A strain of the substrate element, which may be in the form of a monolithic body in particular, therefore leads directly to a deformation of the optical surface determined directly by the strain and distortion of the substrate element according to the laws of solid-state physics.

In a development of the optical apparatus according to the disclosure, provision can be made for the strain gauge device to be at least partly arranged in the at least one actuator, optionally in a groove of the at least one actuator.

In this case, an embodiment of the optical apparatus in which the strain gauge device is arranged completely in the at least one actuator, optionally completely in the groove of the at least one actuator, is particularly advantageous.

An arrangement of the strain gauge device in the at least one actuator is advantageous in that strains and distortions of the at least one actuator can be measured by the strain gauge device in this way.

If strains of the at least one actuator are measured, then this is advantageous in that this can measure an extent and/or a type of the application of force by the at least one actuator which in fact leads to the deformation of the optical surface.

A further feature of arranging the strain gauge device on the at least one actuator is that such an arrangement can be implemented during the manufacture of the at least one actuator. Consequently, the strain gauge device can be formed without having to undertake manipulations on the substrate element which could for example possibly impair mechanical and/or optical properties of the optical surface.

In a development of the optical apparatus according to the disclosure, provision can be made for the strain gauge device to be at least partly arranged, optionally inserted, in the connection layer.

In this case, an embodiment of the optical apparatus in which the strain gauge device is arranged completely in the connection layer, optionally completely inserted therein, is particularly advantageous.

An at least partial arrangement of the strain gauge device on the connection layer is advantageous in that, firstly, the strains and distortions of both the at least one actuator and the substrate element can be measured via the strain gauge device and in that, secondly, the arrangement of the strain gauge device does not require any modification of the at least one actuator and/or of the substrate element.

An arrangement of the strain gauge device in the connection layer is particularly advantageous if the strain gauge device can be inserted, optionally completely, into the latter. By way of example, this is the case when the strain gauge device comprises an optical fiber with a fiber Bragg grating, while the connection layer is produced from an adhesive. In this case, the optical fiber with the fiber Bragg grating can be inserted into the connection layer and optionally be encapsulated by the adhesive such that the formation of the connection layer by the adhesive is not impaired by the optical fiber of the strain gauge device.

In this case, it can be desirable for the strain gauge device to be arranged in the connection layer in such a way that mechanical coupling of the strain gauge device to the at least one actuator and/or to the substrate element is made possible. By way of example, this can be rendered possible by virtue of the adhesive also adhesively bonding the optical fiber of the strain gauge device when the strain gauge device is formed by an adhesive, whereby mechanical coupling arises between the strain gauge device, the connection layer, the substrate element, and the at least one actuator.

For example, provision can be made for parts of the strain gauge device to be arranged in the substrate element, in the at least one actuator, and in the at least one connection layer.

In a development of the optical apparatus according to the disclosure, provision can be made for the at least one fiber Bragg grating to be at least partly arranged in at least one effective region of the at least one actuator.

In the context of the disclosure, the effective region of the at least one actuator should be understood to mean that region of the optical apparatus in which a strain caused by the at least one actuator is able to be measured by the strain gauge device with a sufficient accuracy.

Optionally, provision can be made for each actuator to respectively have a single, optionally path-connected effective region, with effective regions, for example of adjacent actuators, also being able to overlap.

An at least partial arrangement of the at least one fiber Bragg grating in at least one effective region of the at least one actuator is advantageous in that strains triggered by the at least one actuator may trigger changes in the grating period of the fiber Bragg grating, and hence may bring about changes in the fiber interference spectrum which can provide information about the type and extent of the strain.

For example, an arrangement in the effective region of the at least one actuator allows a strain determined by the fiber Bragg grating to be traced back to an actual effect of the at least one actuator. In this case, it is particularly advantageous if the effective regions are separable from one another in the case of a plurality of actuators. As a result, a strain determined by the fiber Bragg grating allows conclusions to be drawn directly about the effect of that actuator in whose effective region the at least one fiber Bragg grating is arranged.

As an alternative or in addition, provision can be made for the fiber Bragg grating to extend over effective regions of a plurality of actuators. As a result, the measured strain is composed of the action of the plurality of actuators. By way of example, actuators can be grouped as a result, and this for example may lead to a reduction in costs since only one fiber Bragg grating is used for a plurality of actuators.

Further, provision can be made for the at least one fiber Bragg grating to extend over the effective regions of a plurality of actuators and for strains of the respective effective regions to lead to a change of different characteristics of the fiber interference spectrum of the fiber Bragg grating in each case.

By way of example, the effective region of the at least one actuator may also comprise a portion of a back plate of the optical apparatus. Accordingly, provision can be made for the at least one fiber Bragg grating to be arranged in the back plate of the optical apparatus. On account of the principle of reaction, a strain in the back plate may be counter to a strain of the substrate element arranged on an opposite side of the actuator. Taking account of this opposite direction, however, a strain of the substrate element and/or optical surface can be deduced from a strain of the back plate.

In a development of the optical apparatus according to the disclosure, provision can be made for the at least one optical fiber to comprise a plurality of fiber Bragg gratings, with the fiber interference spectra of the individual fiber Bragg gratings being designed to be distinguishable.

If the at least one optical fiber comprises a plurality of fiber Bragg gratings, then suitable fitting of the optical fiber allows a plurality of effective regions to be measured by the strain gauge device by way of only one optical fiber. In particular, a plurality of effective regions of a plurality of actuators can be measured via merely one optical fiber. In this case, it is particularly advantageous if the fiber interference spectra of the individual fiber Bragg gratings are formed to be distinguishable within the at least one optical fiber.

A back-reflected spectral range and/or a spectral range of the notch in the radiation spectrum of an individual fiber Bragg grating, and hence a strain on an individual effective region, is hence rendered distinguishable from the strains of the other effective regions of the other fiber Bragg gratings of the one optical fiber. As a result, a plurality of effective regions can be monitored synchronously while evaluating only one reflection and/or transmission spectrum.

Further, provision can be more for the fiber Bragg gratings, in terms of their extent, to be arranged in different spatial directions on the optical apparatus, in particular the substrate element and/or the connection layer and/or the at least one actuator, with the result that strains in different spatial directions are distinguishable from one another.

Provision can be made for the fiber interference spectra to be distinguished from one another to be spectrally separated from one another by 1 nm to 100 nm, such as 1 nm to 10 nm, for example 3 nm to 5 nm.

In a development of the optical apparatus according to the disclosure, provision can be made for at least one spectrometer device to be provided for determining and/or characterizing the fiber interference spectra.

The one or more fiber interference spectra can be examined in full or in part via a spectrometer device.

For example, provision can be made for the spectrometer device to be configured to determine and/or analyze reflected radiation within the fiber bandwidths of the fiber Bragg gratings and/or transmitted fiber spectra with notches within the fiber bandwidth of the fiber Bragg grating. Accordingly, the spectrometer device need not be configured to resolve the full fiber interference spectrum in its full spectral width; instead, the spectrometer device can be restricted to determine and/or characterize particularly characteristic regions of the fiber interference spectra.

In a development of the optical apparatus according to the disclosure, provision can be made for the at least one spectrometer device to be configured to measure a direct frequency shift and/or to comprise a Mach-Zehnder interferometer.

A direct measurement of the frequency shift or wavelength shift of the reflected radiation and/or of the notch in the transmitted radiation spectrum is advantageous in that a restriction to such a relevant part of the spectrum allows a particularly fast and reliable analysis of the fiber interference spectra.

If the at least one spectrometer device comprises a Mach-Zehnder interferometer, then the fiber interference spectrum can be measured and analyzed in a full spectral width. As a result, it is advantageously possible to consider many characteristics of the fiber interference spectra.

In a development of the optical apparatus according to the disclosure, provision can be made for the optical fiber to comprise a plurality of fiber Bragg gratings, extend in loop-shaped fashion, and pass through effective regions of a plurality of actuators.

As a result of a loop-shaped extent of the optical fiber, a plurality of effective regions of a plurality of actuators can be registered by one optical fiber, provided that the optical fiber is dimensioned and configured so that a fiber Bragg grating comes to rest in a majority of the effective regions, optionally in each effective region. As a result of a loop-shaped extent, the effective regions to be measured can each be addressed on an individual basis without the optical fiber crossing itself.

Further, provision can be made for a plurality of fiber Bragg gratings to be arranged in one and the same effective region of an actuator. In this case, the fiber Bragg gratings may for example be oriented differently and/or be arranged in different regions of the effective region. As a result, a strain of the effective region can be measured precisely in three-dimensional space in a particularly advantageous manner.

Alternatively, provision can be made for the optical fiber to have only one fiber Bragg grating, to extend in loop-shaped fashion, and to pass through effective regions of a plurality of actuators.

In a development of the optical apparatus according to the disclosure, provision can be made for
the at least one optical fiber to be guided in meandering fashion through lines and/or rows of a plurality of effective regions, and/or
at least one fiber Bragg grating to be arranged in each of a plurality of effective regions.

Provision can be made for a plurality of actuators, and therewith, a plurality of effective regions to be arranged in rows and lines, which is to say in checkerboard fashion in particular, in the optical apparatus. Firstly, this allows an advantageous systematic application of force by the plurality of actuators and, secondly, production-related simplifications and hence savings in costs can be obtained as a result.

In such a situation, it is particularly advantageous for the at least one optical fiber to be guided in meandering fashion through the lines and rows of the plurality of effective regions. As a result of the meandering extent, the above-described loop-shaped guidance of the optical fiber is made possible in particularly advantageous fashion. In particular, in this context, provision can optionally be made for a fiber Bragg grating to come to rest in a plurality of effective regions, optionally in a majority of effective regions and optionally in each effective region.

In this case, the fiber Bragg gratings are arranged in the individual effective regions which are strained or distorted by the respectively assigned actuators. Between the effective regions, the optical fiber extends without a fiber Bragg grating being arranged in these regions. This is advantageous in that, in the case of a strain of the effective regions, the optical fiber extending between the effective regions can be cut to length or dimensioned such that a distortion of the effective region can be compensated for by a contour length of the fiber and an advantageous maintenance of the beam guidance qualities of the optical fiber can be used. The individual effective regions to be subject to strain and the fiber Bragg gratings arranged therein or thereon are therefore not rigidly interconnected, but interconnected with play by way of the optical fiber.

Provision can be made for a single optical fiber which is assigned to the respective row or line to be present for each line and/or row.

Optionally, provision can be made for at least one fiber Bragg grating to be arranged in each of the effective regions.

Further, provision can be made for each actuator to have only one effective region.

In a development of the optical apparatus according to the disclosure, provision can be made for a back plate to be provided and for the at least one actuator to be arranged between a back plate and the substrate element.

The described embodiment of the optical apparatus with a back plate is advantageous in that the actuators can be operated axially and, in particular, in that an abutment for a strain of the optical surface and/or substrate element is present in the form of the back plate. As a result, an advantageously precise and predictable control or deformation of the optical surface can be achieved since a contour of the totality of all actuators approximately directly defines the deformations of the optical surface.

Further, the presence of a back plate enables a particularly simple assembly of the optical apparatus in an overarching optical installation, in particular in a lithography system such as a projection exposure apparatus, for example.

As an alternative or in addition, provision can be made for the at least one actuator to be connected directly to the optical surface and/or substrate element without the use of a back plate. In this case, actuators with optionally a transverse effect can be used in order to bring about a distortion or strain of the substrate element and/or optical surface. An advantage thereof is that the optical apparatus occupies smaller dimensions as a result of the lack of a back plate, and hence can be attached in space-saving fashion.

In a development of the optical apparatus according to the disclosure, provision can be made for the optical surface to be designed to be light reflective, optionally EUV-reflective and/or DUV-reflective.

If the surface is designed to be light reflective, in particular EUV light reflective, then this allows the use of the optical apparatus as a deformable mirror.

The optical element is optionally a mirror, such as a mirror of a projection exposure apparatus.

As an alternative or in addition, provision can be made for the optical surface to be transparent and be designed as a part of a deformable lens element.

Moreover, the optical element may be a lens element, in particular a lens element of a DUV projection exposure apparatus.

In the method for setting a target deformation of an optical surface of an optical element for a lithography system via one or more actuators, provision is made for an actual deformation of the optical surface to be determined by virtue of at least one actual strain of at least one measurement region being determined.

Within the scope of the disclosure, the measurement region should be understood to mean that region of the optical apparatus in which the actual strain, in particular a change in the actual strain vis-à-vis an original strain, is measurable with a sufficient degree of accuracy.

In the context of the disclosure, each actuator optionally has an effective region, with a measurement region optionally being assigned to the effective region of an actuator.

It can be desirable for the at least one measurement region to fall within at least one effective region of the at least one actuator.

The method according to the disclosure can be desirable in that the actual deformation of the optical surface is determined by a measurement method, specifically the determination of the actual strain of the measurement region. This makes it possible to avoid modeling the actual deformation of the optical surface in advance from the effect of the at least one actuator, as this is particularly susceptible to model errors.

For example, provision can be made for the target deformation to be set by a closed controlled loop, with the actual strain serving as a feedback signal for driving and/or controlling the at least one actuator. As a result, a control loop can be matched particularly accurately to the application of force by the at least one actuator.

An embodiment of the method in which a temperature of the measurement region is determined can be advantageous.

In a development of the method according to the disclosure, provision can be made for the at least one measurement region to be chosen in such a way that the actual deformation of the optical surface can be deduced from the actual strain.

It can be desirable if the at least one measurement region is chosen in such a way that the actual strain determined in the measurement region indicates the actual deformation of the optical surface physically present.

For example, this can be enabled by virtue of the optical surface and the measurement region being mechanically coupled to one another according to the laws of solid state physics and/or of strength of materials, in such a way that this yields at least approximately bijective mapping between the actual deformation of the optical surface and the actual strain of the measurement region.

For example, provision can be made for the actual strain of the at least one measurement region to only indicate the actual deformation of a partial region of the optical surface. Should insight about the actual deformation of the entire optical surface be obtained in such a case, provision can for example be made of a plurality of measurement regions and the determination of a plurality of actual strains, in order to determine the sought-after actual deformation of the entire optical surface.

However, thermal coupling, for example, may also be provided in addition to mechanical coupling of the at least one measurement region, whereby a temperature-related deformation of the optical surface can be deduced from a temperature-related strain of the measurement region provided that a heat transfer between the optical surface and the measurement region can be used for such an exchange of information.

In a development of the method according to the disclosure, provision can be made for a strain gauge device, comprising at least one optical fiber with at least one fiber Bragg grating, to be arranged such that at least one fiber interference spectrum is influenced in at least one of the fiber Bragg gratings of the at least one optical fiber by way of the actual strain of the at least one measurement region.

If the strain gauge device comprises an optical fiber with at least one fiber Bragg grating, then it is advantageous if the optical fiber and/or the fiber Bragg grating are arranged in or on the at least one measurement region in such a way that a fiber interference spectrum of the fiber Bragg grating is influenced by a strain of the at least one measurement region, in particular by the actual strain of the at least one measurement region.

The fiber interference spectrum of a fiber Bragg grating is decisively influenced by the spatial physical properties of the fiber Bragg grating, and hence by the geometry thereof. The fiber interference spectrum can be influenced by a strain and/or compression of the portion of the optical fiber which forms of the fiber Bragg grating. This is successful especially whenever mechanical coupling between the at least one measurement region and the portion of the optical fiber forming the fiber Bragg grating is achieved.

For example, provision can be made for at least one fiber Bragg grating to be arranged in the measurement region for the purpose of measuring the actual strain, in such a way that the measurement region is mechanically decoupled from the fiber Bragg grating or the fiber Bragg grating does not experience a mechanical strain of the measurement region. To this end, it may be advantageous if there is no mechanical coupling between the fiber Bragg grating and the measurement region. As a result, a measured change in the fiber interference spectrum is influenced only by a temperature-induced inherent strain of the fiber Bragg grating. A temperature in the measurement region can be deduced as a result.

This can make it possible to integrate many highly precise sensors into the optical apparatus via a few waveguides, in particular via a few optical fibers and a few fiber Bragg gratings.

In a development of the method according to the disclosure, provision can be made for measurement radiation to be input coupled into the optical fiber.

The input coupled measurement radiation can be of broadband or narrowband form.

The use of broadband measurement radiation is advantageous in that it is possible to measure reflected fiber bandwidths and/or notches in a broad spectral range.

This can render a measurement of a large number of fiber interference spectra and/or the measurement of large spectral shifts in the fiber interference spectra and/or characteristic regions of the fiber interference spectra possible.

Provision can be made for the measurement radiation to be formed by a radiation source with a large bandwidth and for the measurement radiation to be introduced into a waveguide, in particular the optical fiber. If a fiber Bragg grating is also provided, then it is only measurement radiation with a very restricted spectral bandwidth about the central wavelength or Bragg wavelength which is reflected at the fiber Bragg grating. Residual components of the measurement radiation continue their path through the waveguide or the optical fiber, at least approximately without attenuation, up to a next fiber Bragg grating.

Provision can be made for the fiber interference spectrum to be detected via a scanning method, optionally by virtue of
a narrowband measurement radiation with only a narrow wavelength range, in particular a laser radiation, being radiated on the fiber Bragg grating, and
a relative spectral position of the narrow wavelength range being varied over time, for example by way of a tunable laser, as a result of which a broad wavelength band is optionally swept or scanned, and
an intensity of the transmitted and/or reflected measurement radiation being measured in time-resolved fashion, for example via a photodiode, synchronously with the variation of the wavelength range, and
the fiber interference spectrum in the optionally broad wavelength band being determined by comparing the detected intensity of the measurement radiation with the wavelength of the measurement radiation at different times.

Such a scanning method for determining the fiber interference spectrum is particularly reliable and precise.

For example, provision can be made for the fiber Bragg grating to have symmetric design and for the measurement radiation of the order of the central wavelength or Bragg wavelength to be reflected, independently of the side from which the measurement radiation is incident on the fiber Bragg grating.

The central wavelength of the fiber bandwidth or of the Bragg wavelength λ_{B} is defined by a period of the microstructure of the fiber Bragg grating, in particular of the grating period A and a refractive index n_{ef} of a waveguide core, in particular of the fiber core. Formula (2) links a location of the Bragg wavelength λ_{B} to the grating period Λ and the refractive index n_{ef}.

λ_{B}=2n_{ef}Λ (2)

A strain-dependence of the Bragg wavelength λ_{B} can be determined by differentiating the Bragg wavelength λ_{B} in accordance with formula (3). In formula (3), k describes a sensitivity of the strain gauge device and Δε describes a strain of the actuator.

$$\frac{{Δλ}_{B}}{Δε} = k {λ}_{0} \qquad ( 3 )$$

Accordingly, it is rendered possible to generate a sensor signal with respect to the strain of the optical surface or optical element, and consequently possible to determine a physically present actual deformation of the optical surface, in particular of a mirror.

Further, errors during an application of the optical apparatus, for example, can be detected.

By way of example, input coupling of the measurement radiation into the optical fiber can be achieved via a fiber coupler and/or a lens.

In a development of the method according to the disclosure, provision can be made for the fiber interference spectrum of the at least one fiber Bragg grating of the strain gauge device to be determined.

A readout of the fiber interference spectrum allows a highly precise measurement of the change in the geometry of the at least one fiber Bragg grating from a metrological point of view. In general, spectra can be determined particularly reliably via interference methods and therefore allow a particularly precise and accurate determination of the geometry of the at least one fiber Bragg grating, and hence in particular a very precise determination of the actual strain of the at least one measurement region.

By way of example, direct methods for determining a frequency shift and/or interferometric methods, for example using a Mach-Zehnder interferometer, can be used to determine and/or analyze the fiber interference spectrum.

Provision can be made for the measurement radiation used within the scope of the disclosure to have a wavelength from 100 nm to 10 000 nm, such as 300 nm to 3000 nm, for example 1500 nm to 1600 nm.

Provision can be made for the at least one fiber interference spectrum to have wavelengths from 100 nm to 10 000 nm, such as 300 nm to 3000 nm, for example 1500 nm to 1600 nm.

In a development of the method according to the disclosure, provision can be made for the actual deformation of the optical surface to be determined in the lithography system and/or during a reflection of radiation by the optical surface.

The method offers a particular advantage if it is used for the purpose of monitoring the actual deformation of the optical surface in a lithography system since optical surfaces, especially in the case of deformable mirrors, need to satisfy particular properties with respect to a precise embodiment of the surface shape in lithography systems.

It can be desirable for the actual deformation of the optical surface to be determined by the method during an operation of such a mirror formed by the optical surface, especially in the lithography system. The optical surface is exposed to an elevated deposition of energy and hence an increased risk of predicted and uncontrolled strains during an actually occurring reflection of radiation, especially EUV radiation. Controlling the actual deformation of the optical surface is therefore particularly advantageous in order to comprehensively satisfy the object of guiding and shaping the reflected light upon reflection during the operation of the optical surface.

In a development of the method according to the disclosure, provision can be made for the actual strain to be determined in one or more measurement regions in at least one substrate element on which the optical surface is arranged, optionally in a groove of the substrate element.

A determination of the actual strain in the substrate element on which the optical surface is arranged is advantageous in that particularly strong mechanical coupling is formed between the substrate element and the optical surface. This applies especially whenever the optical surface is embodied in the form of a coating and/or structuring of the underlying substrate element.

It can be desirable for the actual strain to be determined in one or more measurement regions which are optionally arranged in a groove within the substrate element. This can yield particularly strong mechanical coupling between the substrate element and the measurement region, and hence the fiber Bragg grating for example. Consequently, strong mechanical coupling is obtained between the fiber Bragg grating, the substrate element, and ultimately the optical surface.

In a development of the method according to the disclosure, provision can be made for the actual strain to be determined in one or more measurement regions in the at least one actuator, optionally in a groove of the actuator.

Determining the actual strain in the at least one actuator is advantageous in that a strain or distortion of the material of the actuator can be measured directly therewith. Since force which is intended to lead to a deformation of the optical surface is generated on the actuator itself, such an arrangement enables particularly tight and direct monitoring of the application of force by the at least one actuator.

It is also true here that a measurement implemented in the actuator, optionally in a groove introduced, more particularly immersed, in the actuator, provides a particularly good indication about strains and distortions in the initial material of the actuator.

In a development of the method according to the disclosure, provision can be made for the actual strain to be determined in one or more measurement regions in at least one connection layer which connects the at least one actuator to the substrate element.

Determining the actual strain in the connection layer is advantageous in that the at least one measurement region can be arranged in the connection layer particularly easily, especially if the connection layer is formed from an adhesive material. As a result, a relative position of the at least one actuator and substrate element can remain virtually unchanged since the measurement region can easily be formed in the newly introduced connection layer.

If the connection layer is further embodied as an adhesive, then the adhesive can advantageously bring about mechanical coupling between the at least one actuator, the measurement region, and the substrate element.

In a development of the method according to the disclosure, provision can be made for the actual strain to be determined synchronously in a plurality of measurement regions.

The actual deformation of the optical surface can advantageously be implemented in full by way of a synchronous determination of a plurality of actual strains at a plurality of measurement regions. A tight grid of measurement regions yields tight scanning of the actual deformation of the optical surface.

Provision can be made for the actual strain to be determined in quick temporal succession in a plurality of measurement regions. In particular, the measurement regions can be read in a multiplexing method.

In this case, it can be desirable for the fiber interference spectra of the fiber Bragg gratings arranged in the plurality of measurement regions to be distinguishable from one another. As a result, a synchronous determination of the fiber interference spectra, and hence the actual strains, is facilitated. In particular, a single optical fiber with a plurality of fiber Bragg gratings can be used here to monitor and control a plurality of measurement regions.

Further, it can be desirable for a shift of the plurality of fiber interference spectra to be examined in the process. A change in the actual strain of the measurement region leads to a shift in the fiber interference spectrum in the case of sufficient mechanical coupling between the fiber Bragg grating and the measurement region, whereby the actual strain can be deduced from the shift in the fiber interference spectrum.

For example, a change in the actual strain may lead to a change in a grating period of the fiber Bragg grating, whereby the central wavelength of the fiber bandwidth of the fiber

Bragg grating shifts in the spectrum, proportionally with the actual strain. As a result, there is a shift in the fiber bandwidth of the reflected light and/or the fiber bandwidth of the notch of the transmitted measurement radiation spectrum, for example.

Provision can be made for the frequency shift in the case of a strain caused by an intended use of the at least one actuator to be 1 pm to 1 nm, such as 5 pm to 500 pm, for example 20 pm to 100 pm.

Provision can be made for a strain resolution in the measurement region to be 1 am to 1 nm, such as 5 am to 1 pm, for example 0.5 fm to 50 fm.

In a development of the method according to the disclosure, provision can be made for the at least one optical fiber to be guided in loop-shaped fashion, optionally in meandering fashion, through lines and/or rows of a plurality of measurement regions, and/or for at least one fiber Bragg grating to be arranged in each of a plurality of measurement regions.

If the at least one optical fiber is guided in meandering fashion through lines and rows of a plurality of measurement regions, then a large number of measurement regions and hence effective regions can be controlled or monitored by the use of only a single optical fiber. Further, an arrangement of the plurality of measurement regions in lines and rows enables a control of the optical surface, for example in the form of grid squares, and this may lead to a particularly advantageous systematic control of the embodiment of the optical surface.

If at least one fiber Bragg grating is arranged in each of a plurality of the measurement regions, which is to say not only in one measurement region, then it is possible to simultaneously control or monitor a plurality of measurement regions. In particular, such a guidance of the optical fiber by the embodiment of fiber Bragg gratings in various regions of the optical fiber makes it possible, already during the production of the optical fiber, to define the measurement regions in which an actual strain should be determined.

Further, a guidance of the optical fiber through the various measurement regions allows offsets between the individual measurement regions and a looser guidance of the optical fiber to avoid a tightening of the fiber as a result of the offset of the measurement regions.

For example, provision can be made for the at least one measurement region in the above-described embodiments of the method to correspond to at least one effective region of the at least one actuator.

This can be desirable since the effective region of the actuator, as the region in which an exertion of force of the actuator leads at least indirectly to a change in the actual deformation of the optical surface, is of particular interest for verifying the effect of the exertion of force by the at least one actuator.

By way of example, if the actual deformation is intended to be determined in a certain region of the optical surface, then it is particularly advantageous if the actual strain is measured in the region in which an effect of the actuator which deforms the region of the optical surface to be examined is measurable.

Provision can be made for a malfunction of the optical apparatus to be determined on the basis of the determined actual strain and/or the determined actual deformation. If a malfunction is present when using the optical apparatus in a lithography system, provision can optionally be made for a current process of the lithography system to be terminated and/or for the error to be transmitted to subsequent processing steps. Further, provision can be made for a responsible party for the machine to be notified for the purposes of analyzing the problem.

A lithography system according to the disclosure, such as a projection exposure apparatus for semiconductor lithography, comprises an illumination system with a radiation source and an optical unit which comprises at least one optical element. According to the disclosure, provision is made for at least one optical apparatus according to the disclosure to be provided, wherein at least one of the optical elements is an optical element of the optical apparatus according to the disclosure and/or at least one of the optical elements has an optical surface which is deformable by way of a method according to the disclosure.

In this context, a deformability should be understood to mean the adjustability of the actual deformation of the optical surface.

The lithography system according to the disclosure can be desirable in that the optical elements or optical surfaces used therein have a particularly precisely controlled optical surface or shape. As a result, particularly reliable imaging can be obtained by the lithography system according to the disclosure, leading to particularly good production results.

Features described in conjunction with one of the subjects of the disclosure, specifically given by the optical apparatus according to the disclosure, the method according to the disclosure, or the lithography system according to the disclosure, are also advantageously implementable for the other subjects of the disclosure. Likewise, advantages specified in conjunction with one of the subjects of the disclosure can also be understood in relation to the other subjects of the disclosure.

Additionally, it should be noted that terms such as “comprising”, “having”, or “with” do not exclude other features or steps. Furthermore, words such as “a(n)” or “the” which indicate single steps or features do not preclude a plurality of features or steps—and vice versa.

However, in a puristic embodiment of the disclosure, provision may also be made for the features introduced in the disclosure using the terms “comprising”, “having”, or “with” to be an exhaustive enumeration. Accordingly, one or more enumerations of features can be considered to be exhaustive within the scope of the disclosure, for example when respectively considered for each claim. By way of example, the disclosure can consist exclusively of the features specified in claim 1.

It should be noted that labels such as “first” or “second”, etc. are used predominantly for reasons of distinguishability between respective apparatus or method features and are not necessarily intended to indicate that features involve one another or are related to one another.

Exemplary embodiments of the disclosure will be described in detail hereinbelow with reference to the drawings.

The figures each show preferred exemplary embodiments in which individual features of the present disclosure are illustrated in combination with one another. Features of any exemplary embodiment are also implementable independently of the other features of the same exemplary embodiment, and may readily be combined accordingly by a person skilled in the art to form further viable combinations and sub-combinations with features of other exemplary embodiments.

In the figures, functionally identical elements are given the same reference signs.

### BRIEF DESCRIPTION OF THE DRAWINGS

In the drawings:

FIG. 1 shows a meridional section of an EUV projection exposure apparatus;

FIG. 2 shows a DUV projection exposure apparatus;

FIG. 3 shows a schematic illustration of an optical apparatus in a rest state;

FIG. 4 shows a schematic illustration of an optical apparatus according to FIG. 3 in a deflected state;

FIG. 5 shows a schematic illustration of a further possible embodiment of the optical apparatus in a rest state;

FIG. 6 shows a schematic illustration of an embodiment according to FIG. 5 in a deflected state;

FIG. 7 shows a schematic illustration of possible strain profiles of an electrostrictive effect at different temperatures;

FIG. 8 shows a schematic illustration of a possible profile of a thermal expansion of an electrostrictive actuator;

FIG. 9 shows a schematic illustration of a possible drift curve of an electrostrictive actuator;

FIG. 10 shows a schematic illustration of a further possible embodiment of the optical apparatus according to the disclosure;

FIG. 11 shows a schematic illustration of a further possible embodiment of the optical apparatus according to the disclosure;

FIG. 12 shows a schematic illustration of a further possible embodiment of the optical apparatus according to the disclosure;

FIG. 13 shows a schematic illustration of a further possible embodiment of the optical apparatus according to the disclosure; and

FIG. 14 shows a schematic illustration of a fiber interference spectrum.

### DETAILED DESCRIPTION

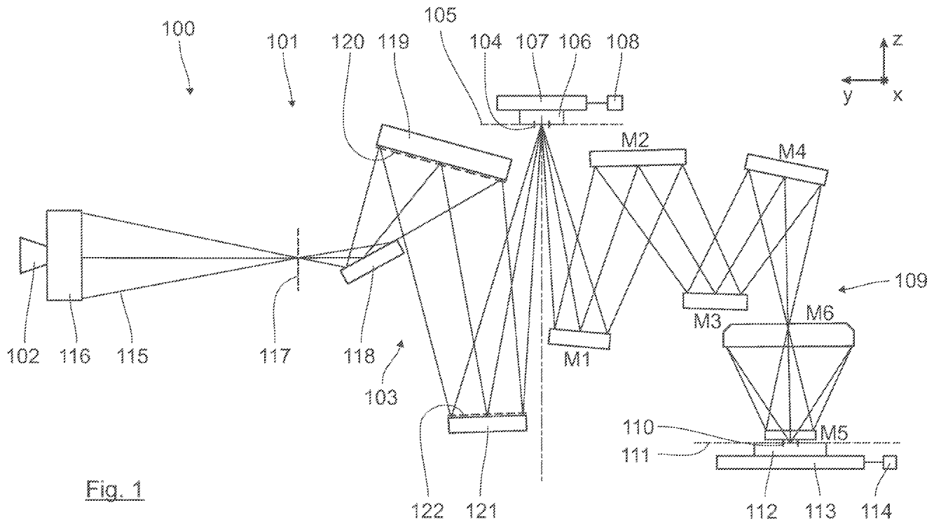

With reference to FIG. 1, certain components of a microlithographic EUV projection exposure apparatus 100 as an example of a lithography system are initially described below in exemplary fashion. The description of the basic structure of the EUV projection exposure apparatus 100 and of the component parts thereof should not be interpreted restrictively here.

An illumination system 101 of the EUV projection exposure apparatus 100 comprises, besides a radiation source 102, an illumination optical unit 103 for the illumination of an object field 104 in an object plane 105. What is exposed here is a reticle 106 arranged in the object field 104. The reticle 106 is held by a reticle holder 107. The reticle holder 107 is displaceable in particular in a scanning direction by way of a reticle displacement drive 108.

In FIG. 1, a Cartesian xyz-coordinate system is plotted to aid the explanation. The x-direction runs perpendicularly into the plane of the drawing. The y-direction runs horizontally, and the z-direction runs vertically. In FIG. 1, the scanning direction runs in the y-direction. The z-direction runs perpendicular to the object plane 105.

The EUV projection exposure apparatus 100 comprises a projection optical unit 109. The projection optical unit 109 serves for imaging the object field 104 into an image field 110 in an image plane 111. The image plane 111 extends parallel to the object plane 105. Alternatively, an angle that differs from 0° between the object plane 105 and the image plane 111 is also possible.

A structure on the reticle 106 is imaged onto a light-sensitive layer of a wafer 112 arranged in the region of the image field 110 in the image plane 111. The wafer 112 is held by a wafer holder 113. The wafer holder 113 is displaceable, in particular in the y-direction, by way of a wafer displacement drive 114. The displacement on the one hand of the reticle 106 by way of the reticle displacement drive 108 and on the other hand of the wafer 112 by way of the wafer displacement drive 114 may take place in such a way as to be synchronized with one another.

The radiation source 102 is an EUV radiation source. The radiation source 102 emits EUV radiation 115, in particular, which is also referred to as used radiation or illumination radiation below. In particular, the used radiation 115 has a wavelength in the range between 5 nm and 30 nm. The radiation source 102 can be a plasma source, for example an LPP source (“laser produced plasma”) or a GDPP source (“gas discharged produced plasma”). It can also be a synchrotron-based radiation source. The radiation source 102 can be a free electron laser (FEL).

The illumination radiation 115 emerging from the radiation source 102 is focused by a collector 116. The collector 116 may be a collector with one or more ellipsoidal and/or hyperboloidal reflection surfaces. The at least one reflection surface of the collector 116 can be impinged upon by the illumination radiation 115 with grazing incidence (GI), which is to say with angles of incidence greater than 45°, or with normal incidence (NI), which is to say with angles of incidence less than 45°. The collector 116 can be structured and/or coated, firstly, for optimizing its reflectivity for the used radiation 115 and, secondly, for suppressing extraneous light.

Downstream of the collector 116, the illumination radiation 115 propagates through an intermediate focus in an intermediate focal plane 117. The intermediate focal plane 117 can represent a separation between a radiation source module, having the radiation source 102 and the collector 116, and the illumination optical unit 103.

The illumination optical unit 103 comprises a deflection mirror 118 and, arranged downstream thereof in the beam path, a first facet mirror 119. The deflection mirror 118 may be a planar deflection mirror or, alternatively, a mirror with a beam-influencing effect going beyond a pure deflection effect. As an alternative or in addition, the deflection mirror 118 may be embodied as a spectral filter that separates a used light wavelength of the illumination radiation 115 from extraneous light of a wavelength deviating therefrom. If the first facet mirror 119 is arranged in a plane of the illumination optical unit 103 that is optically conjugate to the object plane 105 as a field plane, it is also referred to as a field facet mirror. The first facet mirror 119 comprises a multiplicity of individual first facets 120, which are also referred to below as field facets. Only a few of these facets 120 are illustrated in FIG. 1 in exemplary fashion.

The first facets 120 may be embodied as macroscopic facets, in particular as rectangular facets or as facets with an arcuate edge contour or an edge contour of part of a circle. The first facets 120 may be in the form of plane facets or alternatively as facets with convex or concave curvature.

As is known for example from DE 10 2008 009 600 A1, the first facets 120 themselves can also each be composed of a multiplicity of individual mirrors, in particular a multiplicity of micromirrors. The first facet mirror 119 may in particular be in the form of a microelectromechanical system (MEMS system). For details, reference is made to DE 10 2008 009 600 A1.

The illumination radiation 115 travels horizontally, which is to say in the y-direction, between the collector 116 and the deflection mirror 118.

In the beam path of the illumination optical unit 103, a second facet mirror 121 is arranged downstream of the first facet mirror 119. If the second facet mirror 121 is arranged in a pupil plane of the illumination optical unit 103, it is also referred to as a pupil facet mirror. The second facet mirror 121 can also be arranged at a distance from a pupil plane of the illumination optical unit 103. In this case, the combination of the first facet mirror 119 and the second facet mirror 121 is also referred to as a specular reflector. Specular reflectors are known from US 2006/0132747 A1, EP 1 614 008 B1, and U.S. Pat. No. 6,573,978.

The second facet mirror 121 comprises a plurality of second facets 122. In the case of a pupil facet mirror, the second facets 122 are also referred to as pupil facets.

The second facets 122 may likewise be macroscopic facets, which may for example have a round, rectangular or hexagonal boundary, or may alternatively be facets composed of micromirrors. In this regard, reference is likewise made to DE 10 2008 009 600 A1.

The second facets 122 may have plane reflection surfaces or alternatively reflection surfaces with a convex or concave curvature.

The illumination optical unit 103 consequently forms a double-faceted system. This basic principle is also referred to as fly's eye integrator.

It may be advantageous to arrange the second facet mirror 121 not exactly in a plane that is optically conjugate to a pupil plane of the projection optical unit 109.

With the aid of the second facet mirror 121, the individual first facets 120 are imaged into the object field 104. The second facet mirror 121 is the last beam-shaping mirror or indeed the last mirror for the illumination radiation 115 in the beam path upstream of the object field 104.

In a further embodiment of the illumination optical unit 103 (not illustrated), a transfer optical unit can be arranged in the beam path between the second facet mirror 121 and the object field 104, the transfer optical unit contributing to the imaging of the first facets 120 into the object field 104, in particular. The transfer optical unit can comprise exactly one mirror or, alternatively, two or more mirrors, which are arranged in succession in the beam path of the illumination optical unit 103. In particular, the transfer optical unit can comprise one or two mirrors for normal incidence (NI mirror, “normal incidence” mirror) and/or one or two mirrors for grazing incidence (GI mirror, “grazing incidence” mirror).

In the embodiment shown in FIG. 1, the illumination optical unit 103 comprises exactly three mirrors downstream of the collector 116, specifically the deflection mirror 118, the field facet mirror 119, and the pupil facet mirror 121.

The deflection mirror 118 can also be dispensed with in a further embodiment of the illumination optical unit 103, and so the illumination optical unit 103 can then have exactly two mirrors downstream of the collector 116, specifically the first facet mirror 119 and the second facet mirror 121.

The imaging of the first facets 120 into the object plane 105 via the second facets 122 or using the second facets 122 and a transfer optical unit is, as a rule, only approximate imaging.

The projection optical unit 109 comprises a plurality of mirrors Mi, which are numbered in accordance with their arrangement in the beam path of the EUV projection exposure apparatus 100.

In the example illustrated in FIG. 1, the projection optical unit 109 comprises six mirrors M1 to M6. Alternatives with four, eight, ten, twelve, or any other number of mirrors Mi are likewise possible. The penultimate mirror M5 and the last mirror M6 each have a through opening for the illumination radiation 115. The projection optical unit 109 is a doubly obscured optical unit. The projection optical unit 109 has an image-side numerical aperture which is greater than 0.5 and which can also be greater than 0.6 and, for example, can be 0.7 or 0.75.

Reflection surfaces of the mirrors Mi can be in the form of free-form surfaces without an axis of rotational symmetry. Alternatively, the reflection surfaces of the mirrors Mi can be designed as aspherical surfaces with exactly one axis of rotational symmetry of the reflection surface shape. Just like the mirrors of the illumination optical unit 103, the mirrors Mi can have highly reflective coatings for the illumination radiation 115. These coatings can be designed as multilayer coatings, in particular with alternating layers of molybdenum and silicon.

The projection optical unit 109 has a large object-image offset in the y-direction between a y-coordinate of a center of the object field 104 and a y-coordinate of the center of the image field 110. In the y-direction, this object-image offset can be of approximately the same magnitude as a z-di stance between the object plane 105 and the image plane 111.

The projection optical unit 109 may in particular have an anamorphic form. In particular, it has different imaging scales βx, βy in the x- and y-directions. The two imaging scales βx, βy of the projection optical unit 109 can be (βx, βy)=(+/−0.25, +/−0.125). A positive imaging scale β means imaging without image inversion. A negative sign for the imaging scale β means imaging with image inversion.

The projection optical unit 109 consequently leads to a reduction in size with a ratio of 4:1 in the x-direction, which is to say in a direction perpendicular to the scanning direction.

The projection optical unit 109 leads to a reduction in size of 8:1 in the y-direction, which is to say in the scanning direction.

Other imaging scales are likewise possible. Imaging scales with the same signs and the same absolute values in the x-direction and y-direction are also possible, for example with absolute values of 0.125 or 0.25.

The number of intermediate image planes in the x-direction and in the y-direction in the beam path between the object field 104 and the image field 110 can be the same or can differ depending on the embodiment of the projection optical unit 109. Examples of projection optical units with different numbers of such intermediate images in the x- and y-directions are known from US 2018/0074303 A1.

In each case one of the pupil facets 122 is assigned to exactly one of the field facets 120 for forming in each case an illumination channel for illuminating the object field 104. This may in particular produce illumination according to the Köhler principle. The far field is decomposed into a multiplicity of object fields 104 with the aid of the field facets 120. The field facets 120 generate a plurality of images of the intermediate focus on the pupil facets 122 respectively assigned thereto.

By way of an assigned pupil facet 122, the field facets 120 are imaged in each case onto the reticle 106 in a manner overlaid on one another for the purpose of illuminating the object field 104. The illumination of the object field 104 is in particular as homogeneous as possible. It optionally has a uniformity error of less than 2%. Field uniformity can be attained by overlaying different illumination channels.

The illumination of the entrance pupil of the projection optical unit 109 can be defined geometrically by way of an arrangement of the pupil facets. The intensity distribution in the entrance pupil of the projection optical unit 109 can be set via the selection of the illumination channels, in particular the subset of the pupil facets which guide light. This intensity distribution is also referred to as illumination setting.

A likewise preferred pupil uniformity in the region of sections of an illumination pupil of the illumination optical unit 103 that are illuminated in a defined manner can be achieved by a redistribution of the illumination channels.

Further aspects and details of the illumination of the object field 104 and in particular of the entrance pupil of the projection optical unit 109 are described hereinbelow.

The projection optical unit 109 may in particular have a homocentric entrance pupil. The latter can be accessible. It can also be inaccessible.

The entrance pupil of the projection optical unit 109 generally cannot be illuminated exactly via the pupil facet mirror 121. The aperture rays often do not intersect at a single point when imaging the projection optical unit 109 which telecentrically images the center of the pupil facet mirror 121 onto the wafer 112. However, it is possible to find a surface area in which the spacing of the aperture rays that is determined in pairs becomes minimal. This surface area represents the entrance pupil or an area in real space that is conjugate thereto. In particular, this area has a finite curvature.

The projection optical unit 109 might have different poses of the entrance pupil for the tangential beam path and for the sagittal beam path. In this case, an imaging element, in particular an optical component part of the transfer optical unit, should be provided between the second facet mirror 121 and the reticle 106. With the aid of this optical component, it is possible to take account of the different poses of the tangential entrance pupil and the sagittal entrance pupil.

In the arrangement of the components of the illumination optical unit 103 illustrated in FIG. 1, the pupil facet mirror 121 is arranged in an area conjugate to the entrance pupil of the projection optical unit 109. The first field facet mirror 119 is arranged so as to be tilted in relation to the object plane 105. The first facet mirror 119 is arranged so as to be tilted in relation to an arrangement plane defined by the deflection mirror 118.

The first facet mirror 119 is arranged so as to be tilted in relation to an arrangement plane defined by the second facet mirror 121.

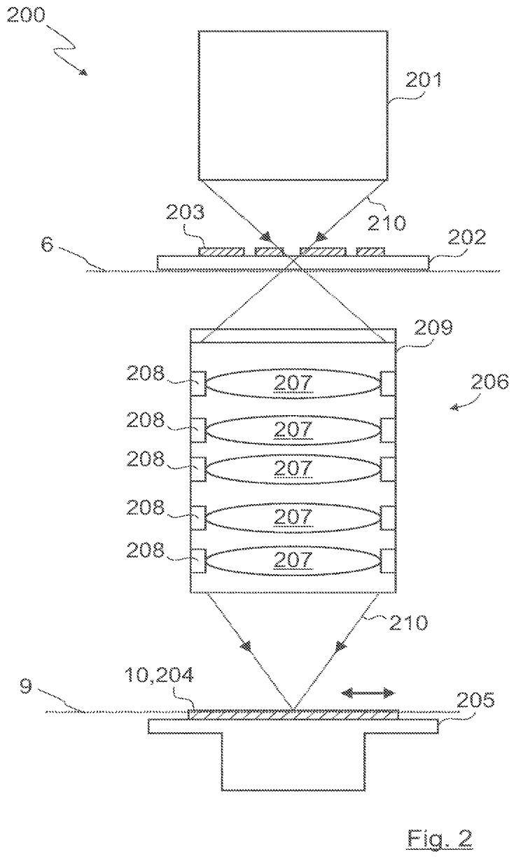

FIG. 2 shows an exemplary DUV projection exposure apparatus 200. The DUV projection exposure apparatus 200 comprises an illumination system 201, a device known as a reticle stage 202 for receiving and exactly positioning a reticle 203 by which the later structures on a wafer 204 are determined, a wafer holder 205 for holding, moving, and exactly positioning the wafer 204, and an imaging device, specifically a projection optical unit 206, with a plurality of optical elements, in particular lens elements 207, which are held by way of mounts 208 in a lens housing 209 of the projection optical unit 206.

As an alternative or in addition to the lens elements 207 illustrated, provision can be made of various refractive, diffractive, and/or reflective optical elements, inter alia also mirrors, prisms, terminating plates, and the like.

The basic functional principle of the DUV projection exposure apparatus 200 makes provision for the structures introduced into the reticle 203 to be imaged onto the wafer 204.

The illumination system 201 provides a projection beam 210 in the form of electromagnetic radiation, which is used for the imaging of the reticle 203 onto the wafer 204. The source used for this radiation may be a laser, a plasma source, or the like. The radiation is shaped in the illumination system 201 via optical elements such that the projection beam 210 has the desired properties with regard to diameter, polarization, and shape of the wavefront, and the like when it is incident on the reticle 203.

An image of the reticle 203 is generated via the projection beam 210 and transferred from the projection optical unit 206 onto the wafer 204 in an appropriately reduced form. In this case, the reticle 203 and the wafer 204 can be moved synchronously, so that regions of the reticle 203 are imaged onto corresponding regions of the wafer 204 virtually continuously during what is called a scanning operation.

An air gap between the last lens element 207 and the wafer 204 can optionally be replaced by a liquid medium which has a refractive index of greater than 1.0. The liquid medium can be high-purity water, for example. Such a set-up is also referred to as immersion lithography and has an increased photolithographic resolution.

The use of the disclosure is not restricted to use in projection exposure apparatuses 100, 200, in particular also not with the described structure. The disclosure is suitable for any lithography system, but in particular for projection exposure apparatuses having the described structure. The disclosure is also suitable for EUV projection exposure apparatuses which have a smaller image-side numerical aperture than those described in the context of FIG. 1, and which have no obscured mirror(s) M5 and/or M6. In particular, the disclosure is also suitable for EUV projection exposure apparatuses which have an image-side numerical aperture from 0.25 to 0.5, such as 0.3 to 0.4, for example 0.33. The disclosure and the following exemplary embodiments should also not be understood as being restricted to a specific design. The figures that follow illustrate the disclosure merely by way of example and in highly schematized form.

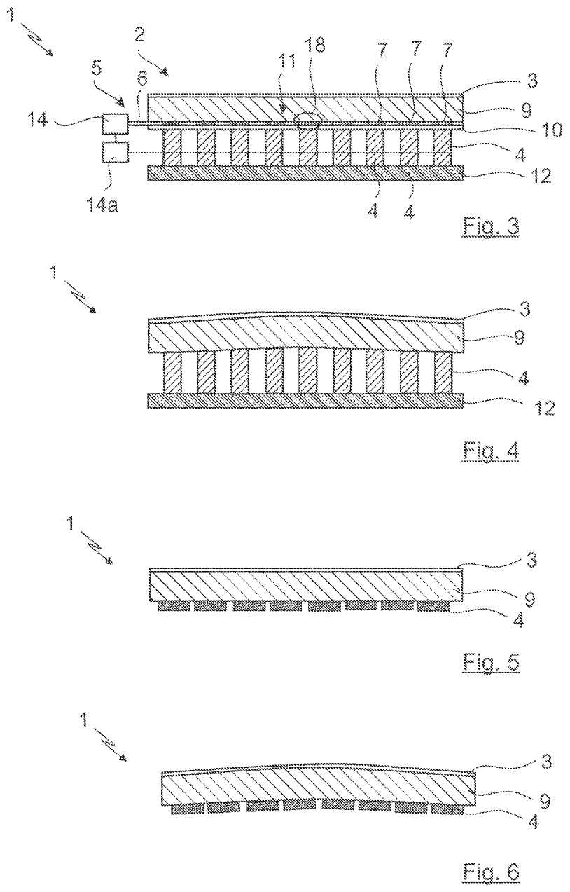

FIG. 3 shows a schematic illustration of an optical apparatus 1.

The optical apparatus 1, depicted in the exemplary embodiment, for a lithography system, in particular for a projection exposure apparatus 100, 200, comprises at least one optical element 2, which has an optical surface 3, and a plurality of actuators 4 for deforming the optical surface 3. Further, a strain gauge device 5 for determining the deformation of the optical surface 3 is provided or present.

In an embodiment (not depicted here), provision can be made for only one actuator 4 to be present for a deformation of the optical surface 3. In this case, it is advantageous if the one actuator 4 can, where possible, deform the optical surface 3 in all spatial directions.

The strain gauge device 5 comprises at least one optical fiber 6.

In this case, the optical fiber 6 is polarization maintaining.

Further, in the exemplary embodiment depicted in FIG. 3, the at least one optical fiber 6 of the optical apparatus 1 comprises a plurality of fiber Bragg gratings 7 with respective fiber interference spectra 8 (see FIG. 14).

Moreover, in the exemplary embodiment of the optical apparatus 1 depicted in FIG. 3, the optical element 2 comprises a substrate element 9 on which the optical surface 3 is arranged or formed. Further, the actuators 4 are connected to the substrate element 9 by way of a connection layer 10.

In the exemplary embodiment depicted in FIG. 3, the connection layer 10 comprises an adhesive. The connection layer 10 may also be formed by other materials in other embodiments.

In the exemplary embodiment depicted in FIG. 3, the strain gauge device 5 further is at least partly arranged in the connection layer 10.

In particular, the strain gauge device 5 has been inserted into the connection layer 10 in the exemplary embodiment depicted in FIG. 3.

Further, FIG. 3 shows an embodiment of the optical apparatus 1, in which the at least one fiber Bragg grating 7 is at least partly arranged in at least one effective region 11 of the actuators 4.

A fiber Bragg grating 7 is optionally assigned to a plurality, optionally to a majority, and particularly optionally to all of the effective regions 11. In this case, each actuator 4 optionally forms a dedicated effective region 11 for deforming or shaping the optical surface 3 of the optical element 2.

A back plate 12 is optionally present in the exemplary embodiment of the optical apparatus 1 depicted in FIG. 3. In this case, the actuators 4 are optionally arranged between the back plate 12 and the substrate element 9. The back plate 12 enables a support of the actuators 4 which operate normally (orthogonally) to the optical surface 3 in the exemplary embodiment depicted in FIG. 3.

The optical fiber 6 comprises a plurality of fiber Bragg gratings 7, the fiber interference spectra 8 (see FIG. 14) of which are optionally formed in distinguishable fashion.

In particular, the fiber Bragg gratings 7 have different grating periods in the depicted exemplary embodiment.

FIG. 3 also shows an embodiment of the optical apparatus 1, in which at least one spectrometer device 14 is present for the purpose of determining and characterizing one or more fiber interference spectra 8.

Further, a closed-loop control device 14a is present in the exemplary embodiment depicted in FIG. 3 and is configured to set the target deformation by way of a closed control loop. In this case, the actual strain serves as a feedback signal for driving and/or controlling the at least one actuator 4. As a result, the control loop can be matched particularly accurately to the application of force by the at least one actuator 4. Operative corrections are depicted by dashed lines in FIG. 3.

The spectrometer device 14 is optionally configured to measure a direct frequency shift in the fiber interference spectra 8. As an alternative or in addition, provision can be made for the spectrometer device 14 to comprise a Mach-Zehnder interferometer.

Further, in the optical apparatus 1 depicted in FIG. 3, the optical surface 3 has a light-reflective, in particular EUV light-reflective, embodiment.

In an alternative embodiment, provision can be made for the optical surface 3 to have a DUV light-reflective embodiment.

FIG. 4 shows a schematic illustration of the optical apparatus 1. The optical surface 3 is deformed by the effect of the actuators 4 in the depicted exemplary embodiment. The actuators 4 are supported against the back plate 12 and operate in a direction which runs approximately parallel to a surface normal of the optical surface 3.

Strains arise in the substrate element 9 as a result of the effect of the actuators 4 and are measurable, for example via the strain gauge device 5 (not depicted in FIG. 4).

FIG. 5 shows a simplified schematic illustration of the optical apparatus 1, wherein a back plate 12 was dispensed with and the actuators 4 have an operating direction which runs at least approximately parallel to the optical surface 3.

FIG. 6 shows the optical apparatus 1 of FIG. 5 in a deflected state.

Accordingly, FIGS. 3 to 6 depict different systems for actuating deformable optical surfaces 3, in particular mirror surfaces. Accordingly, FIGS. 3 and 4 show an actuation normal (orthogonal) to the optical surface 3 and FIGS. 5 and 6 show an actuation parallel to the optical surface 3.

In the exemplary embodiment depicted in FIGS. 3 and 4, a plurality of actuators 4 can exert a compressive force on the optical element 2 and consequently precisely deform or shape the latter. In the exemplary embodiment depicted in FIGS. 5 and 6, a bending moment is introduced into the optical element 2 and/or optical surface 3 by way of a strain and/or a contraction of the actuators 4, and this may lead to a deformation of the optical element and/or optical surface.

FIG. 7 shows a schematic illustration of different strain curves of the actuators 4.

A strain of the actuator 4 and/or a strain of the effective region 11 of the actuator 4 is plotted on a vertical strain axis 15.

In FIG. 7, the field strength of an applied electric field is plotted on a horizontal axis 16. The diagram in FIG. 7 plots four strain curves, which correspond to different temperatures of the actuator 4. All four strain curves exhibit hysteresis.

In this case, the strain curve with the lowest profile corresponds to the highest temperature, while the strain curve with the highest profile corresponds to the lowest temperature of the actuator 4.

The strain curves of the actuator 4 depicted in FIG. 7 reproduce the behavior of the actuator 4 according to formula (1). A hysteresis of the actuator 4 is evident here and is of the order of <1% in the depicted example.

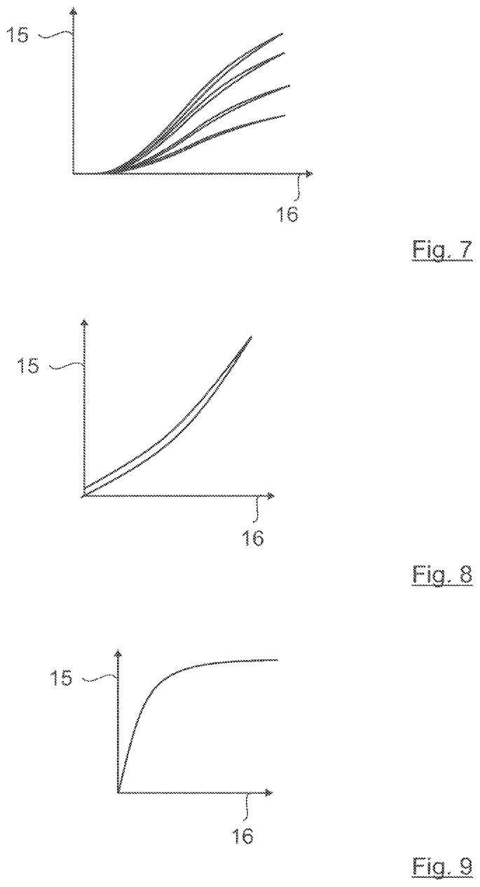

FIG. 8 shows a schematic illustration of a strain curve of the actuator 4 under a temperature change. The strain axis 15 once again plots the strain of the actuator 4, while the horizontal axis 16 plots the temperature of the actuator 4. A hysteresis of the strain curve when running through a temperature cycle is evident.

The lengthening of the actuator 4 in the case of the change in temperature vis-à-vis the normal temperature, which is arranged at the origin of the diagram depicted in FIG. 8, is determined in particular by the coefficient of thermal expansion CTE (see formula (1)). A thermal hysteresis of the strain is evident in the strain curve depicted in FIG. 8. In this case, the effect of the hysteresis may be non-reproducible.

FIG. 9 shows a schematic illustration of a drift curve of the actuator 4. The strain axis plots the strain of the actuator 4, while the horizontal axis 16 plots a course of time. The actuator 4 is at an initial position or has an initial strain at the origin, which is to say at the start of the time measurement, and receives a signal, optionally in the form of an applied voltage, to adopt a target position, which is to say a target strain. Over time, the actuator 4 approaches the target position or the target strain, or drifts there-toward.

Further, the drift depicted in FIG. 9 may depend on the respective step height of the actuator 4.

FIG. 10 shows a sectional view of a schematic illustration of a possible embodiment of the optical apparatus 1.

In this case, the optical fiber 6 comprises a plurality of fiber Bragg gratings 7, extends in loop-shaped fashion, and passes through the effective regions 11 of a plurality of actuators 4.

Further, in the exemplary embodiment depicted in FIG. 10, the optical fiber 6 is guided in meandering fashion through rows of a plurality of effective regions 11. In an alternative exemplary embodiment, provision can be made for the at least one optical fiber 6 to be additionally or alternatively guided in meandering fashion through lines of a plurality of effective regions 11.

A plurality of optical fibers 6 extending in meandering fashion may also be provided in the exemplary embodiment depicted in FIG. 10.

As an alternative or in addition, a plurality of optical fibers 6 which are each assigned to a line or row may also be provided in the exemplary embodiment depicted in FIG. 10.

Further, at least one fiber Bragg grating 7 is arranged in each of a plurality of effective regions 11 in the exemplary embodiment depicted in FIG. 10.

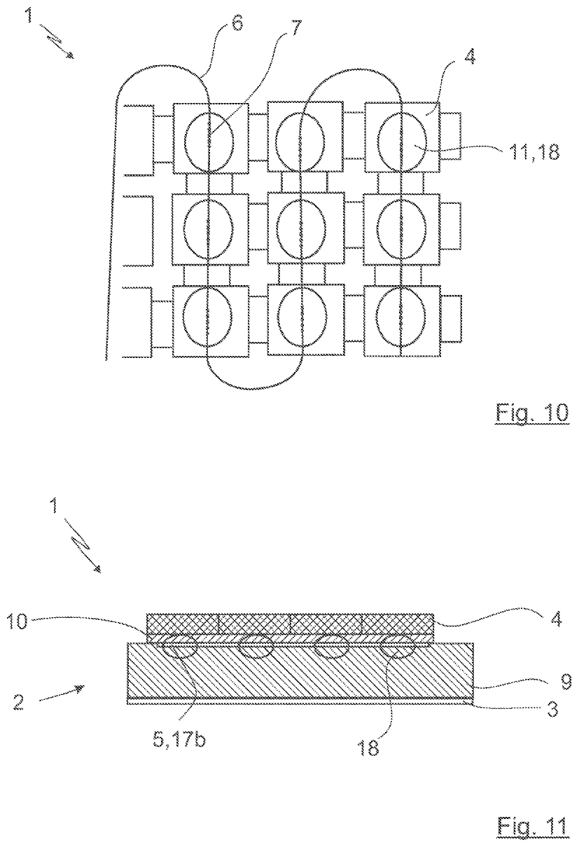

FIG. 11 shows a schematic illustration of a further possible embodiment of the optical apparatus 1, wherein the strain gauge device 5 is arranged at least in part, optionally in full, in the substrate element 9. In particular, the strain gauge device 5 is arranged in a groove 17b in the depicted exemplary embodiment.

The strain gauge device 5 may also be arranged both in the substrate element 9 and in the connection layer 10.

FIG. 11 depicts a section through an actuator 4 with a connection layer 10 and the substrate element 9. In the exemplary embodiment depicted in FIG. 11, the actuators 4 lie extensively on the connection layer 10 which connects the actuators 4 and the substrate element 9.

In the exemplary embodiment depicted in FIG. 11, the groove 17b has optionally been milled into the substrate element 9.

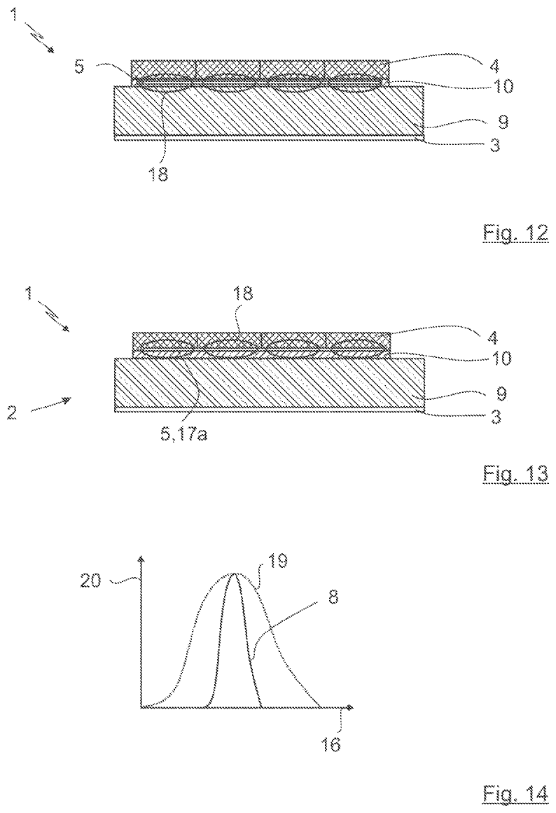

FIG. 12 shows a further schematic illustration of the embodiment of the optical apparatus 1, whereby the strain gauge device 5 is arranged, in particular inserted, at least in part, optionally in full, in the connection layer 10.

FIG. 13 shows a schematic illustration of an embodiment of the optical apparatus 1, wherein the strain gauge device 5 is at least partly arranged in the at least one actuator 4, in particular in the groove 17a.

The strain gauge device 5 may also be arranged both in the at least one actuator 4 and in the connection layer 10.

The strain gauge device 5 may also be arranged both in the substrate element 9 and in the at least one actuator 4.

The strain gauge device 5 may also be arranged in the substrate element 9, in the connection layer 10, and in the at least one actuator 4.

In the exemplary embodiment depicted in FIG. 13, the groove 17a has optionally been milled into the actuators 4.

Features mentioned in an exemplary embodiment of FIGS. 3 to 13 can also be implemented in the other exemplary embodiments. In particular, it is also possible to use a plurality of optical fibers which are arranged in the optical element 2 in the manner described on the basis of FIGS. 11 and/or 12 and/or 13.

The exemplary embodiments of the optical apparatus 1 depicted in FIGS. 3 to 13 are also particularly suitable for carrying out a method for setting a target deformation of the optical surface 3 of the optical element 2 for a lithography system 100, 200 via the one or more actuators 4. In the method, provision is made for an actual deformation of the optical surface 3 to be determined by virtue of at least one actual strain of at least one measurement region 18 being determined. Further, the at least one measurement region 18 is chosen in such a way that the actual deformation of the optical surface 3 can be deduced from the actual strain.

In the exemplary embodiments, the measurement regions 18 are optionally chosen so that a measurement region 18 is assigned to each effective region 11, at least to each effective region 11 which should be measured or observed, wherein the respective measurement region 18 is optionally situated or formed within the effective region 11.

Further, to carry out the method, the strain gauge device 5 is optionally arranged such that the fiber interference spectrum 8 in the fiber Bragg gratings 7 of the optical fiber 6 is influenced by the actual strain of the at least one measurement region 18.

Further, a broadband measurement radiation 19 is input coupled into the optical fiber 6 for the purpose of carrying out the method. That is to say, the method according to the disclosure optionally comprises the input coupling of the broadband measurement radiation 19.

The fiber interference spectra 8 of the fiber Bragg gratings 7 of the strain gauge device 5 can be determined using the measurement radiation.

As an alternative or in addition, provision can be made for a narrowband measurement radiation 19 to be input coupled into the optical fiber 6 and for the fiber interference spectra 8 to be determined in a scanning method by sweeping or scanning a sufficiently broad wavelength band.

Further, provision is optionally made for the actual deformation of the optical surface 3 to be determined in the lithography systems 100, 200 according to FIGS. 1 and 2 and during a reflection by the optical surface 3 of an operating radiation of the projection exposure apparatus 100, 200.

The embodiment of the optical device 1 depicted in FIG. 11 is particularly suitable for carrying out an embodiment of the method, whereby the actual strain in a plurality of measurement regions 18 in the substrate elements 9 which underlie the optical surface 3 is determined in the groove 17b.

The exemplary embodiment of the optical device 1 depicted in FIG. 12 is suitable to a particularly great extent for carrying out an embodiment of the method, whereby the actual strain in a plurality of measurement regions 18 is determined in the connection layer which connects the actuators 4 to the substrate element 9.

The exemplary embodiment of the optical device 1 depicted in FIG. 13 is suitable to a particularly great extent for carrying out an embodiment of the method, whereby the actual strain in a plurality of measurement regions 18 in the actuators 4 is determined in the groove 17a.

Further, the method optionally provides for the actual strain in the plurality of measurement regions 18 to be determined synchronously and/or in a fast temporal succession.

The exemplary embodiment of the optical device 1 depicted in FIG. 10 is suitable to a particularly great extent for carrying out an embodiment of the method, whereby the optical fiber 6 is guided in meandering fashion through rows of a plurality of measurement regions 18. Further, at least one fiber Bragg grating 7 is optionally arranged in each of a plurality of the measurement regions 18 in this embodiment.

As an alternative or in addition, provision can be made for the at least one optical fiber 6 to be guided in meandering fashion through lines of a plurality of measurement regions 18.

FIG. 14 shows a schematic illustration of the fiber interference spectrum 8. The wavelength is plotted on the horizontal axis 16. The measured spectrum 8 of back-reflected measurement radiation 19 is plotted using a solid line on the intensity axis 20. An input spectrum of the radiated-in measurement radiation 19 is plotted using a dashed line.

### LIST OF REFERENCE SIGNS

1 Optical apparatus
2 Optical element
3 Optical surface
4 Actuator
5 Strain gauge device
6 Optical fiber
7 Fiber Bragg grating
8 Fiber interference spectrum
9 Substrate element
10 Connection layer
11 Effective region
12 Back plate
14 Spectrometer device
15 Strain axis
16 Horizontal axis
17a,b Grooves
18 Measurement region
19 Measurement radiation
20 Intensity axis
100 EUV projection exposure apparatus
101 Illumination system
102 Radiation source
103 Illumination optical unit
104 Object field
105 Object plane
106 Reticle
107 Reticle holder
108 Reticle displacement drive
109 Projection optical unit
110 Image field
111 Image plane
112 Wafer
113 Wafer holder
114 Wafer displacement drive
115 EUV/used/illumination radiation
116 Collector
117 Intermediate focal plane
118 Deflection mirror
119 First facet mirror/field facet mirror
120 First facets/field facets
121 Second facet mirror/pupil facet mirror
122 Second facets/pupil facets
200 DUV projection exposure apparatus
201 Illumination system
202 Reticle stage
203 Reticle
204 Wafer
205 Wafer holder
206 Projection optical unit
207 Lens element
208 Mount
209 Lens housing
210 Projection beam
Mi Mirrors

What is claimed is:

1. An optical apparatus, comprising:
an optical element comprising an optical surface;
an actuator configured to deform the optical surface; and
a strain gauge device configured to determine a deformation of the optical surface,
wherein the strain gauge device comprises an optical fiber configured to maintain polarization.

2. The optical apparatus of claim 1, wherein the optical fiber comprises a fiber Bragg grating configured to yield a fiber interference spectrum.

3. The optical apparatus of claim 2, wherein the fiber Bragg grating is at least partly arranged in an effective region of the actuator.

4. The optical apparatus of claim 3, wherein the optical fiber comprises a plurality of fiber Bragg gratings extending in loop-shaped fashion and passing through the effective regions of a plurality of actuators.

5. The optical apparatus of claim 2, wherein the optical fiber is guided in meandering fashion through lines and/or rows of a plurality of effective regions, and/or the fiber Bragg grating is arranged in each of a plurality of effective regions.

6. The optical apparatus of claim 2, wherein the optical fiber comprises a plurality of fiber Bragg gratings, and fiber interference spectra yielded by the individual fiber Bragg gratings are distinguishable.

7. The optical apparatus of claim 2, further comprising a spectrometer device configured to determine and/or characterize the fiber interference spectrum.

8. The optical apparatus of claim 7, wherein the spectrometer device is configured to measure a direct frequency shift, and/or the spectrometer device comprises a Mach-Zehnder interferometer.

9. The optical apparatus of claim 1, wherein the optical element comprises a substrate element supporting the optical surface.

10. The optical apparatus of claim 9, further comprising an adhesive layer connecting the actuator to the substrate element.

11. The optical apparatus of claim 10, wherein the strain gauge device is at least partly arranged in the adhesive layer.

12. The optical apparatus of claim 9, wherein the strain gauge device is at least partly arranged in the substrate element.

13. The optical apparatus of claim 9, further comprising a back plate, wherein the actuator is between the back plate and the substrate element.

14. The optical apparatus of claim 1, wherein the strain gauge device is at least partly arranged in the actuator.

15. The optical apparatus of claim 1, wherein the optical surface is light reflective.

16. An apparatus, comprising:
a radiation source;
an optical unit comprising the optical apparatus of claim 1,
wherein the apparatus is a semiconductor lithography projection exposure apparatus.

17. A method of using an actuator to set a target deformation of an optical surface of an optical element of a lithography system, the method comprising:
determining an actual deformation of the optical surface by virtue of an actual strain of a measurement region,
wherein a strain gauge device is provided for determining the deformation of the optical surface, and the strain gauge device comprising an optical fiber configured to maintaining polarization.

18. The method of claim 17, wherein the at least one measurement region is configured so that the actual deformation of the optical surface can be deduced from the actual strain.

19. The method of claim 17, wherein the strain gauge device comprises a fiber Bragg grating configured so that a fiber interference spectrum is influenced in the fiber Bragg grating by way of the actual strain of the measurement region.

20. The method of claim 19, wherein the optical fiber is guided in loop-shaped fashion through lines and/or rows of a plurality of measurement regions, and/or a fiber Bragg grating is arranged in each of a plurality of measurement regions.

21. The method of claim 19, further comprising coupling measurement radiation into the optical fiber.

22. The method of claim 19, further comprising determining the fiber interference spectrum.

23. The method of claim 17, further comprising determining the actual deformation of the optical surface in the lithography system and/or during a reflection of radiation by the optical surface).

24. The method of claim 17, further comprising determining the actual strain in the measurement regions in a substrate element that supports the optical surface.

25. The method of claim 23, further comprising determining the actual strain in the measurement region in a connection layer connecting the actuator to the substrate element.

26. The method of claim 17, further comprising determining the actual strain in the measurement region.

27. The method of claim 17, further comprising synchronously determining the actual strain in a plurality of measurement regions.
